(19) United States
(12) Patent Application Publication
(10) Pub. No.: US 2006/0169315 A1
(43) Pub. Date: Aug. 3, 2006

(54) Modular photovoltaic solar power system

(76) Inventor: Alexander Levin, Binyamina (IL)

Correspondence Address: Alexander Levin, 5A Shvil Hachalav St., Binyamina, 30500, IL

(21) Appl. No.: 11/047,047

(22) Filed: Feb. 1, 2005

(51) Int. Cl. H01L 31/042

(52) U.S. Cl. 136/251; 136/246

(57) ABSTRACT

The invention relates to photovoltaic solar power systems and more specifically to solar photovoltaic systems which include concentrators of solar radiation. The invention includes application of single curvature and compound-curvature concentrators. A supporting member with an installed photovoltaic cell serves as an element in a heat sink unit and, at the same time, as a detail of a tracking mechanism. It allows to construct a cheap and reliable photovoltaic solar power system.

### BACKGROUND OF THE INVENTION

This invention relates to photovoltaic solar power systems and more specifically to solar photovoltaic systems, which include concentrators of solar radiation.

It is known, that high cost of solar photovoltaic cells limits their wide application as renewable source of electrical energy. Usage of relatively cheap concentrators of solar radiation allows to diminish significantly the fraction of cost of a photovoltaic cell in the total cost of the photovoltaic solar power system and to achieve in such a way decrease of required investment per unit of generated power of this system.

This approach provides some advantages to solar concentrating photovoltaic systems as compared to common photovoltaic flat-plate systems. The concentrators ensure higher efficiency of converting solar radiation into electricity by photovoltaic solar cells. At the same time, significant reducing the size of the solar cells gives possibility to apply more expensive solar cells with higher efficiency and improved stability of their output characteristics at high temperatures.

On the other hand, there are some technical problems to be solved in using concentrators of solar radiation. These problems relate to design of a suitable tracking mechanism and dissipation of heat releasing on the photovoltaic cells.

There are some US patents, which are related to the area of solar photovoltaic systems with application of concentrators of solar radiation. For example, it is possible to mention U.S. Pat. Nos. 4,056,405, 4,361,717, 4,604,494, 4,971,633 and 5,374,317.

However, there is a necessity in technical solutions, which provide cheap and reliable constructions of solar photovoltaic power systems with application of concentrators of solar radiation.

### BRIEF SUMMARY OF THE INVENTION

This invention proposes some relatively simple and reliable constructions of modular solar photovoltaic power systems with application of the concentrators of solar radiation.

In the case of application of single curvature tracking concentrators, such construction includes some main units:

Posts with a bearing pipe installed on these posts; the bearing pipe serves for removal of heat released on photovoltaic solar cells by a liquid medium flowing in it and, in addition, this bearing pipe serves as an axle for tracking motion of a single curvature concentrator after the sun. The bearing pipe can be provided with a layer of thermal insulation. It allows to utilize better the heat releasing on the photovoltaic solar cells.

A supporting member that is fabricated from metal with high thermal conductivity, this supporting member has a plane surface, which serves for installation of the photovoltaic cell, and an opposite concave cylindrical surface with radius nearly equal to the radius of the bearing pipe; the supporting member should be positioned on the bearing pipe and can be turned around it. In such a way, the supporting member and the bearing pipe constitute a cylindrical hinge.

The solar photovoltaic cell itself that is installed with good thermal contact on the plane surface of the supporting member. The term “solar photovoltaic cell” implies in this invention solar cells themselves, solar cell modules and arrays of solar cell modules.

The abovementioned single curvature concentrator of solar radiation in the form of a parabolic trough-wise mirror, this parabolic trough-wise mirror is provided with a frame, which is joined with the supporting member by some truss struts.

A tracking mechanism, which causes turning the single curvature concentrator and the supporting member in such a way that solar radiation, which is reflected from this concentrator, comes mainly on the surface of the solar cell. This tracking mechanism includes a set of tracking rods joined with the frames of the single curvature concentrators, actuating units serving for displacement of the tracking rods and a control unit.

It should be noted that several supporting members with associated solar cells and concentrators can be positioned on one bearing pipe.

The proposed solar photovoltaic power system includes as well some auxiliary units: a system of cooling the liquid medium; a unit for conditioning electrical current generated by the array of the solar cells. The system of cooling the liquid medium can include units for utilization of heat accumulated by the liquid medium.

The aforementioned cylindrical hinge can be provided with a liquid lubricant in order to diminish friction between the supporting member and the bearing pipe.

There is an elastic element in the form of a Ω-wise flat spring (or springs), two extreme sections of this flat spring are installed on the supporting member and its middle section passes over the bearing pipe. In such a way, this Ω-wise flat spring ensures good mechanical and thermal contact between the bearing pipe and the supporting member.

In addition, the cylindrical hinge can be protected by a longitudinal cap from above in order to minimize ingress of moisture and dust into this cylindrical hinge.

The cylindrical surface of the supporting member, the outer surfaces of the bearing pipe and the internal surface of the Ω-wise flat spring can be provided with antifriction coatings.

It is possible to apply a single curvature Fresnel mirror instead of the single curvature parabolic mirror in the form of a trough.

In addition, it is possible to apply two tilted mirrors in the form of strips installed on the edges of the photovoltaic solar cell; the aperture formed by these strips is covered by a plate of diffusing glass with high value of the light transmission coefficient. This allows to provide uniform distribution of the concentrated solar radiation on the surface of the photovoltaic solar cell.

The photovoltaic solar power system itself comprises a number of the modules described above, where these modules are arranged in series and in parallel; the modules, which arranged in series, have the common bearing pipe and the modules arranged in parallel have the common tracking rods. It should be noted, that it is possible to apply tracking ropes instead of the tracking rods. This allows to use the tracking rods from material with very low coefficient of thermal expansion (for example, the ropes fabricated from quartz fibers). Application of such ropes provides high precision of tracking.

In the case of application of compound-curvature concentrators in the form of dish-type mirrors, a module of the proposed system comprises a bearing pipe that is mounted on the vertical posts. The bearing pipe can be provided with a layer of thermal insulation. It allows to achieve better utilization of the heat releasing on the photovoltaic solar cells.

Some T-pieces are built into the bearing pipe. The lower branch of each T-piece is sealed by a metal convex hemi-spherical cap.

The upper side of a metal supporting member has the concave surface in the form of a spherical segment with the radius almost identical to that of metal convex hemi-spherical cap. In such a way, this pair: the hemi-spherical cap of the T-piece and the concave surface of the supporting member present a spherical joint.

The supporting member is assembled with the bearing pipe by some springs; tension of these springs ensures tight mechanical and thermal contact between the hemi-spherical cap and the supporting member.

A liquid lubricant can be used for diminishment of friction in this spherical joint.

The contacting surfaces of this spherical joint can be provided with antifriction coatings.

In addition, it is possible to apply a concave cap in the form of a spherical segment, which seals the lower branch of the T-piece, and a convex surface in the form of a hemi-sphere of the supporting member; this convex surface should be in tight mechanical and thermal contact with the concave surface of the cap.

In such a way, the supporting member with all units installed on it can be turned with respect to the convex or concave surface of the cap.

The lower side of the supporting member has a plane surface intended for installation of the photovoltaic solar cell.

In addition, the supporting member is provided with the spring eyes, each spring eye serves for joining with one end of a spring, the other end of the spring is joined with an auxiliary detail mounted on the bearing pipe. There is the abovementioned compound-curvature concentrator of solar radiation in the form of a parabolic dish mirror and its frame; this frame is joined with the supporting member by some truss struts.

It is possible to apply a compound-curvature Fresnel mirror instead of the compound-curvature parabolic dish mirror.

The set of the modules with the compound-curvature concentrators is provided with a common mechanism of tracking, which includes tracking rods, mechanisms of actuation of the tracking rods and a control unit.

In order to provide homogenous distribution of the concentrated solar radiation on the surface of the solar cell, it is possible to apply an auxiliary optical element, which allows to redistribute concentrated solar radiation that has a form of converging conical beam on a square solar cell. Operation of this auxiliary optical element can be based on principles of non-imaging optics. For example, the auxiliary optic element may be constructed as a funnel with reflecting inner walls; the wide opening of this funnel has the circular form which is deformed at the opposite opening of the funnel into the square form. In addition, the inner reflecting wall of the funnel can be provided with such waviness and roughness that it ensures more uniform distribution of the concentrated radiation on the solar cell.

### BRIEF DESCRIPTION OF THE SEVERAL VIEWS OF THE DRAWING

FIG. 1 shows is a cross-section of two adjacent photovoltaic concentrator modules arranged in parallel with a common tracking rod and with trough-wise parabolic concentrators.

FIG. 2 demonstrates a top view of the photovoltaic concentrator module with the trough-wise parabolic concentrator.

FIG. 3 shows a cross-section of a combined unit of a bearing pipe and a supporting member in the case of application of the trough-wise parabolic concentrator.

FIG. 4 shows a cross-section of a photovoltaic concentrator module with a dish-type parabolic concentrator.

FIG. 5 demonstrates a cross-section of a combined unit of the bearing pipe and the supporting member of the photovoltaic concentrator module with the dish-type parabolic concentrator.

FIG. 6 shows a top view of the combined unit of the bearing pipe and the supporting member of the photovoltaic concentrator module with the dish-type parabolic concentrator.

### DETAILED DESCRIPTION OF THE INVENTION

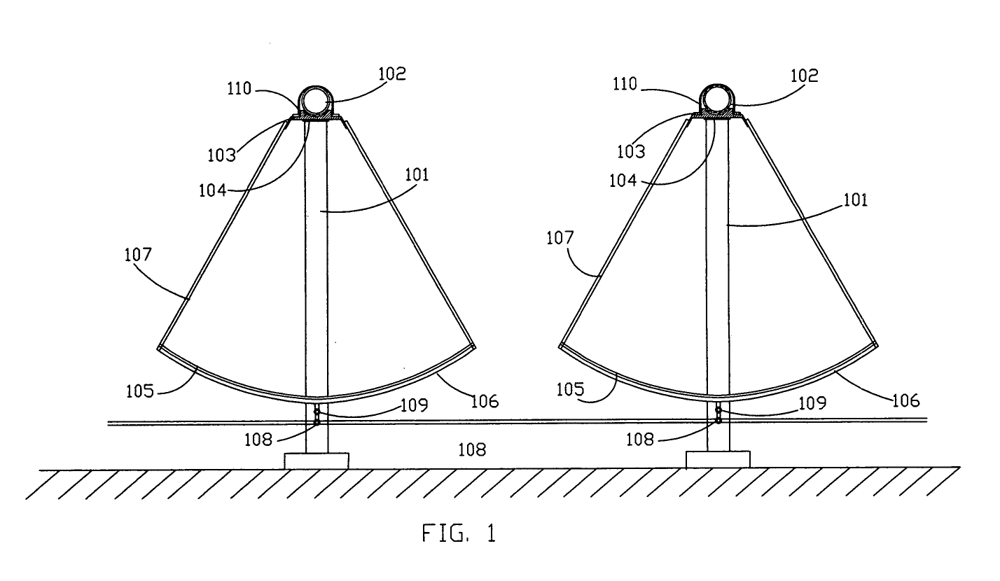

Referring to the drawings and particularly to FIG. 1, this drawing demonstrates a cross-section of two adjacent photovoltaic concentrator modules arranged in parallel with a common tracking rod and trough-wise parabolic concentrators. It comprises posts 101 with bearing pipes 102, supporting members 103 with solar cells 104 installed on their low surfaces, parabolic troughs 105 with frames 106; these frames 106 are joined with the supporting members 103 by truss struts 107.

The tracking rod 108 is joined with frames 106 through cylindrical hinges 108 and 109. Ω-wise spring elements 110 hold the supporting members 103 with all other elements installed on these supporting members; in such a way, this Ω-wise spring elements 110 ensure good thermal contact between the bearing pipes 101 and the supporting members 103.

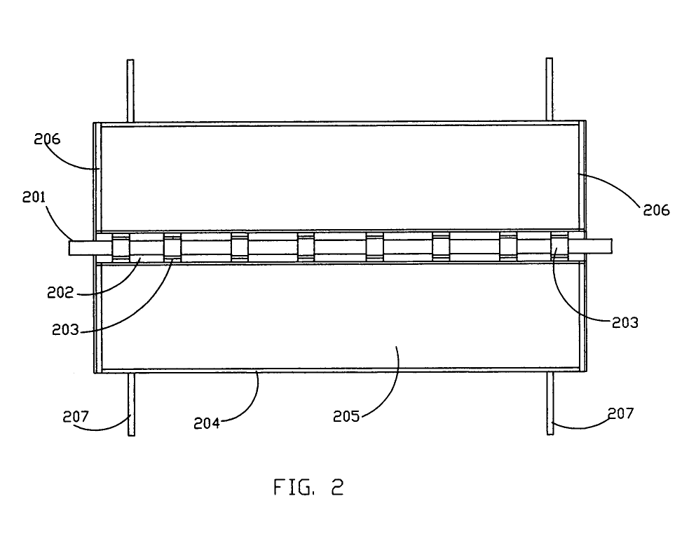

FIG. 2 demonstrates a top view of the photovoltaic concentrator module with the trough-wise parabolic concentrator. It comprises a bearing pipe 201, a supporting member 202, Ω-wise spring elements 203, frame 204 of a trough-wise parabolic reflector 205, truss struts 206 and tracking rods 207.

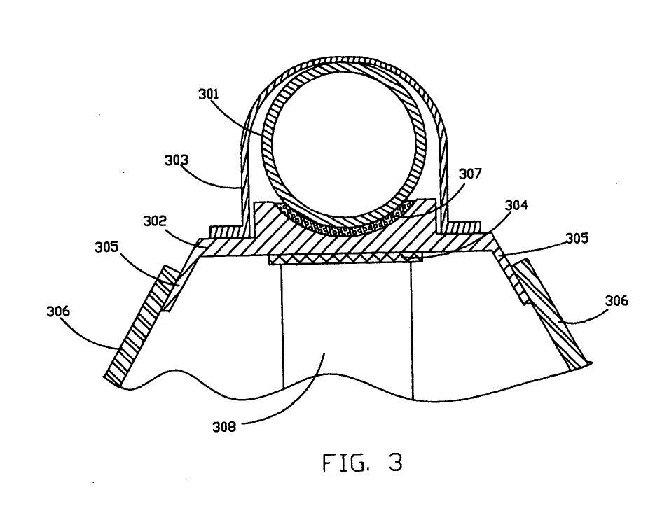

FIG. 3 shows a cross-section of a combined unit of a bearing pipe and a supporting member in the case of application of the trough-wise parabolic concentrator or another type of a single curvature concentrator. It includes: a bearing pipe 301; a supporting member 302 that is installed on this bearing pipe by a Ω-wise spring element 303. A solar cell 304 is situated on the lower side of the supporting member 302.

The lateral walls 305 of the supporting member 302 are joined with truss struts 306.

A thin layer 307 of lubricant with good thermal conductivity is situated in the gap between the supporting member 302 and the bearing pipe 301. The bearing pipe 301 is supported by post 308.

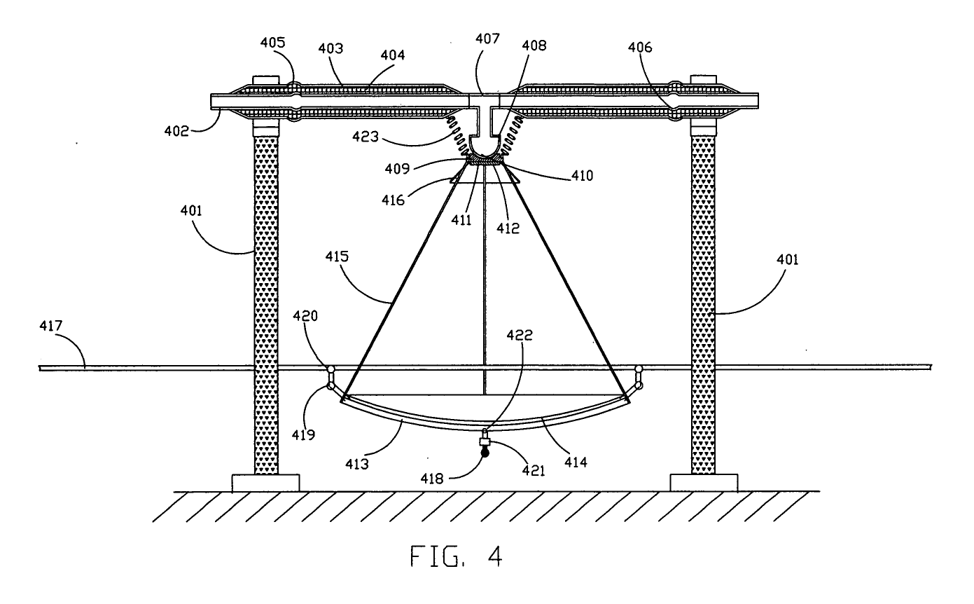

FIG. 4 shows a cross-section of a photovoltaic concentrator module with a dish-type parabolic concentrator. It comprises posts 401, which support a bearing pipe 402 with an external envelope 403 and a thermal insulation layer 404. In addition, the bearing pipe 402 and the external envelope 403 are provided with flexible joints 405 and 406. The bearing pipe 402 incorporates a central T-piece 407. The lower branch of this T-piece is sealed with a hemi-spherical cap 408. A supporting member 409 has an upper depression 410 with the surface of a spherical segment, the radius of this depression conforms the radius of the hemi-spherical cap 408.

The lower side of the supporting member 409 has a planar surface 411, it serves for installation of a photovoltaic solar cell 412.

In addition, the supporting member 409 serves for mounting frame 413 with a dish-type reflector 414 by truss struts 415. Funnel 416 has the reflecting inner surface, the circular lower aperture and the square upper aperture. This funnel is installed on the supporting member 409 and it serves for transformation of converging conical light beam into the light that is incident on the square surface of the photovoltaic solar cell 412.

Tracking rods 417 and 418 perform tracking the dish-type reflector 414 in two directions; these tracking rods are joined with frame 413 of the dish-type reflector 414 through cylindrical hinges 419, 420, 421 and 422.

The supporting member 409 is held by springs 423 with respect to the bearing pipe 402.

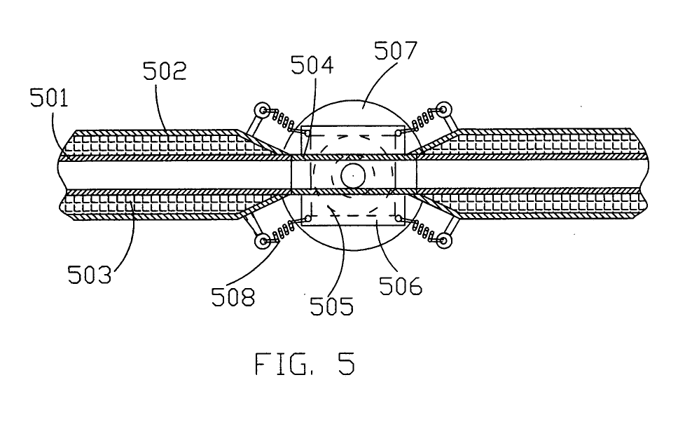

FIG. 5 demonstrates a cross-section of a combined unit of the bearing pipe and the supporting member of the photovoltaic concentrator module with the dish-type parabolic concentrator. It comprises: a bearing pipe 501 with an external envelope 502 and a thermal insulation layer 503; a T-piece 504, the lower branch of this T-piece 504 is sealed by a hemi-spherical cap 505. A supporting member 506 has an upper depression with the surface of a spherical segment, the radius of this depression conforms the radius of the hemi-spherical cap 505.

The lower side of the supporting member 506 has a planar surface; it serves for installation of a photovoltaic solar cell.

Funnel 507 has the reflecting inner surface, the circular lower aperture and the square upper aperture. This funnel is installed on the supporting member 506 and it serves for transformation of converging conical light beam into the light that is incident on the square surface of the photovoltaic solar cell.

The supporting member 506 is held by springs 508 with respect to the bearing pipe 501.

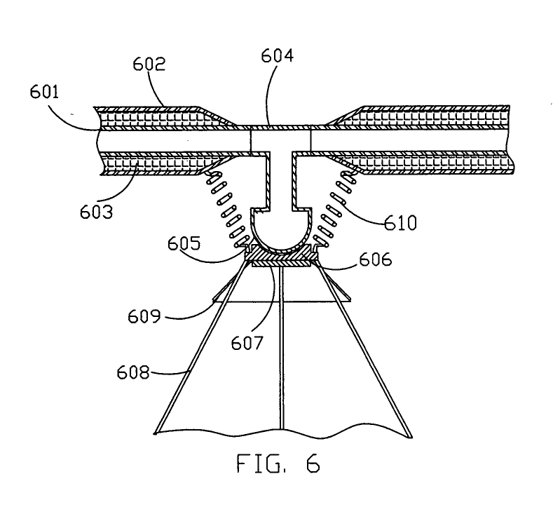

FIG. 6 shows a top view of the combined unit of the bearing pipe and the supporting member of the photovoltaic concentrator module with the dish-type parabolic concentrator. It comprises a bearing pipe 601 with an external envelope 602 and a thermal insulation layer 603; a T-piece 604, the lower branch of this T-piece is sealed by a hemi-spherical cap 605. A supporting member 606 has an upper depression with the surface of a spherical segment, the radius of this depression conforms the radius of the hemi-spherical cap 605.

The lower side of the supporting member 606 has a planar surface that serves for installation of a photovoltaic solar cell 607. In addition, there are funnel 609, which transforms converging conical light beam into the light that is incident on the square surface of the photovoltaic solar cell 607, and truss struts 608.

The supporting member 606 is held by springs 610 with respect to the external envelope 602.

What is claimed is:

1. A modular photovoltaic solar power system consisting of a set of modules, each said module comprises:
two posts with a bearing pipe installed on said posts, said bearing pipe serves for heat removal by a liquid medium flowing in it;
a supporting member that is fabricated from metal with high thermal conductivity, said supporting member has a plane surface, which serves for installation of a solar photovoltaic cell, and an opposite concave cylindrical surface, which should be positioned on said bearing pipe and can be turned around said bearing pipe; in such a way, said supporting member and said bearing pipe present a cylindrical hinge;
said solar photovoltaic cell that is installed with good thermal contact on said plane surface of said supporting member;
a single curvature concentrator of solar radiation in the form of parabolic trough-wise mirror, a frame of said single curvature concentrator is joined with said supporting member by some truss struts; said bearing pipe serves as an axle for tracking motion of said single curvature concentrator after the sun;
elastic elements, which hold said supporting member in tight mechanical and thermal contact with said bearing pipe;
said modular photovoltaic solar power system includes as well some auxiliary units: a unit of cooling said liquid medium; a tracking mechanism, which causes turning said single curvature concentrators and said supporting members in such a way that solar radiation reflected from said single curvature concentrators comes mainly on the surface of said solar photovoltaic cells; said tracking mechanism includes a set of tracking rods, which are joined with said frames of said single curvature concentrators or with said truss struts through cylindrical hinges; actuators for pulling said tracking rods; a control unit; a unit for conditioning electrical current generated by the array of said solar cells.

2. A modular photovoltaic solar power system as claimed in claim 1, wherein said elastic elements have the form of O-wise flat springs.

3. A modular photovoltaic solar power system as claimed in claim 1, wherein said unit of cooling said liquid medium includes a unit for utilization of heat accumulated by said liquid medium.

4. A modular photovoltaic solar power system as claimed in claim 1, wherein said single curvature concentrator has the form of a parabolic cylindrical mirror.

5. A modular photovoltaic solar power system as claimed in claim 1, wherein said single curvature concentrator has the form of a Fresnel parabolic single curvature mirror.

6. A modular photovoltaic solar power system as claimed in claim 1, wherein said concave cylindrical surface of said supporting member is provided with lubricant.

7. A modular photovoltaic solar power system as claimed in claim 1, wherein said concave cylindrical surface of said supporting member and/or said bearing pipe and/or the inner surface of said elastic element are provided with an antifriction coating(s).

8. A modular photovoltaic solar power system as claimed in claim 1, wherein said bearing pipe is protected by a longitudinal cap from above in order to minimize ingress of moisture and dust into the cylindrical hinge formed by said bearing pipe, said supporting member and said elastic element.

9. A modular photovoltaic solar power system as claimed in claim 1, wherein there are two tilted mirrors in the form of strips installed on the edges of said photovoltaic solar cell; the aperture formed by said strips is covered by a plate of diffusing glass with high value of its light transmission coefficient; it allows to achieve high degree of uniformity of concentrated solar radiation on said photovoltaic solar sell.

10. A modular photovoltaic solar power system as claimed in claim 1, wherein a tracking rope is used instead of said tracking rod.

11. A modular photovoltaic solar power system as claimed in claim 10, wherein said tracking rope is fabricated from a material with low coefficient of thermal expansion (for example, said tracking ropes are fabricated from quartz fibers).

12. A modular photovoltaic solar power system consisting of a set of modules, each said module comprises:
two posts with a bearing pipe installed on said posts, said bearing pipe serves for heat removal by a liquid medium flowing in it;
some T-pieces are built into said bearing pipe; the lower branch of each said T-piece is sealed by a metal convex hemi-spherical cap;
a metal supporting member, the upper side of said metal supporting member has the concave surface in the form of a spherical segment with the same radius as the radius of said hemi-spherical cap of said T-piece; in such a way, this pair: said hemi-spherical cap of said T-piece and said concave surface of said supporting member present a spherical joint and said supporting member with all units installed on it can turn in two directions with respect to the convex surface of said cap;
some springs, which join said supporting member with said bearing pipe; tension of said springs ensures tight mechanical and thermal contact between said hemi-spherical cap and said supporting member;
a photovoltaic solar cell, which is installed on the lower side of said supporting member; said lower side of said supporting member has the plane surface;
said supporting member is provided with spring eyes, each said spring eye serves for joining with one end of said spring, and the other end of said spring is joined with an auxiliary detail mounted on said bearing pipe;
a compound-curvature concentrator of solar radiation in the form of a dish mirror with a frame; said compound-curvature concentrator is joined with said supporting member by some truss struts;
said modular photovoltaic solar power system includes as well some auxiliary units: a system of cooling said liquid medium, a tracking mechanism, which causes turning said compound-curvature concentrators and said supporting members in such a way, that solar radiation reflected from said compound-curvature concentrators comes mainly on the surfaces of said solar photovoltaic cells; said tracking mechanism includes a set of tracking rods or ropes, which are joined with said frames of said compound-curvature concentrators or with said truss struts through cylindrical hinges; a mechanism of actuation of said tracking rods and a control unit; a unit for conditioning electrical current generated by the array of said solar cells; a unit for cooling said liquid medium.

13. A modular photovoltaic solar power system as claimed in claim 12, wherein liquid lubricant is used for diminishment of friction in said spherical joint.

14. A modular photovoltaic solar power system as claimed in claim 12, wherein the contacting surfaces of said spherical joint are provided with antifriction coatings.

15. A modular photovoltaic solar power system as claimed in claim 12, wherein a concave cap in the form of a spherical segment seals the lower branch of said T-piece, and the upper surface of said supporting member has a form of a convex hemi-sphere;
said convex surface of said supporting member should be in tight mechanical and thermal contact with said concave surface of said cap.

16. A modular photovoltaic solar power system as claimed in claim 12, wherein a compound-curvature Fresnel mirror is used instead of said parabolic compound-curvature concentrator in the form of a dish.

17. A modular photovoltaic solar power system as claimed in claim 12, wherein there is an auxiliary optical element, which provides homogenous distribution of the concentrated solar radiation on the surface of said solar cell by redistribution of concentrated solar radiation onto said square photovoltaic solar cell.

18. A modular photovoltaic solar power system as claimed in claim 17, wherein said auxiliary optical element is constructed as a funnel with reflecting inner walls; the wide opening of said funnel has the circular form, which is deformed at the opposite opening of said funnel into the square form.

19. A modular photovoltaic solar power system as claimed in claim 18, wherein the inner reflecting walls of said funnel are provided with such waviness and roughness, that it ensures more uniform distribution of the concentrated solar radiation on said photovoltaic solar cell.
